(19) United States
(12) Patent Application Publication
(10) Pub. No.: US 2020/0328254 A1
(43) Pub. Date: Oct. 15, 2020

(54) MEMORY CELL AND MANUFACTURING METHOD THEREOF AND MEMORY DEVICE

(71) Applicants: Jiangsu Advanced Memory Technology Co., Ltd., Jiangsu (CN); Jiangsu Advanced Memory Semiconductor Co., Ltd., Jiangsu (CN)

(72) Inventors: Yu-Cheng LIAO, Hsinchu County (TW); Chun-Chih LIU, Hsinchu County (TW); Yi-Cheng LEE, Hsinchu County (TW)

(21) Appl. No.: 16/423,187

(22) Filed: May 28, 2019

(30) Foreign Application Priority Data
Apr. 10, 2019 (CN) 201910283835.5

(51) Int. Cl. H01L 27/24; H01L 45/00; H01L 29/66; H01L 29/786; H01L 21/324; H01L 21/265; H01L 29/417

(52) U.S. Cl. CPC H01L 27/2436; H01L 45/06; H01L 45/126; H01L 27/2463; H01L 45/1666; H01L 29/41775; H01L 29/66757; H01L 29/78666; H01L 21/324; H01L 21/26506; H01L 45/1608

(57) ABSTRACT

The present disclosure discloses a memory cell and a memory device including the same. The memory cell includes a thin film transistor layer, a gate conductive layer, a first heater, a second heater, a phase change layer, and a dielectric layer. The thin film transistor layer includes a channel layer and a first source/drain structure and a second source/drain structure in contact with opposite sides of the channel layer. The gate conductive layer is disposed beneath the gate dielectric layer to control turn-on or turn-off of the channel layer. The first and second heaters are respectively disposed over the first and second source/drain structures. The phase change layer is disposed over the channel layer and in contact with the first and second heaters. The dielectric layer is disposed beneath the phase change layer, and the phase change layer is separated from the channel layer by the dielectric layer.

### CROSS-REFERENCE TO RELATED APPLICATION

This application claims priority to China Application Serial Number 201910283835.5, filed Apr. 10, 2019, which is herein incorporated by reference.

### BACKGROUND

### Field of Invention

The present disclosure relates to a memory cell and a manufacturing method thereof, and a memory device including the memory cell.

### Description of Related Art

Flash memory is a non-volatile memory. The flash memory can hold saved data information in the memory even without an external power supply. Flash memory is composed of many storage units. Conventional flash memory system utilizes a floating gate transistor as a storage unit and determines the state of storage based on the amount of charge stored on the floating gate.

However, conventional flash memory has disadvantages such as a high operating voltage, a complicated structure and thus difficulty in manufacturing, a slow programming and reading speed, and a low endurance. Therefore, there is a need in the industry for a flash memory that is novel and does not have the above disadvantages.

### SUMMARY

An aspect of the present disclosure provides a memory cell including a thin film transistor layer, a gate dielectric layer, a gate conductive layer, a first heater, a second heater, a phase change layer, and a dielectric layer. The thin film transistor layer includes a channel layer and a first source/drain structure and a second source/drain structure in contact with opposite sides of the channel layer. The gate dielectric layer is disposed beneath the thin film transistor layer. The gate conductive layer is disposed beneath the gate dielectric layer to control turn-on or turn-off of the channel layer. The first and second heaters are respectively disposed over the first and second source/drain structures. The phase change layer is disposed over the channel layer and in contact with the first and second heaters. The dielectric layer is disposed beneath the phase change layer, and the phase change layer is separated from the channel layer by the dielectric layer.

In an embodiment of the present disclosure, the phase change layer is disposed over the first heater and the second heater, and bottoms of both ends of the phase change layer are in contact with the first heater and the second heater.

In an embodiment of the present disclosure, an upper surface of the first heater, an upper surface of the second heater, and an upper surface of the dielectric layer are coplanar.

In an embodiment of the present disclosure, the phase change layer is disposed between the first heater and the second heater, and sidewalls of both ends of the phase change layer are in contact with the first heater and the second heater.

In an embodiment of the present disclosure, an upper surface of the first heater, an upper surface of the second heater, and an upper surface of the phase change layer are coplanar.

In an embodiment of the present disclosure, the memory cell further includes a gate metal layer disposed beneath the gate conductive layer.

Another aspect of the present disclosure is to provide a memory device including a plurality of the above-mentioned memory cells connected in series.

Another aspect of the present disclosure provides a method of manufacturing a memory cell, including: (i) providing a precursor structure, the precursor structure including: a substrate; and a gate conductive layer disposed over the substrate; (ii) forming a gate dielectric layer over the gate conductive layer; (iii) forming a thin film transistor layer over the gate dielectric layer, in which the thin film transistor layer includes a channel layer, and a first source/drain structure and a second source/drain structure in contact with two sides of the channel layer, in which the channel layer is completely covered by the gate dielectric layer in a direction perpendicular to a projection; (iv) forming a first heater and a second heater over the first source/drain structure and the second source/drain structure; and (v) forming a phase change layer in contact with the first heater and the second heater.

In an embodiment of the present disclosure, the operation of providing the precursor structure includes: forming a dielectric layer over the substrate; patterning the dielectric layer to form a patterned dielectric layer having an opening; and forming a gate conductive layer in the opening.

In an embodiment of the present disclosure, the operation of forming the thin film transistor layer includes: forming an amorphous silicon layer over the gate dielectric layer; performing an annealing process to crystallize the amorphous silicon layer to form a polysilicon layer or a single-crystal silicon layer; and performing an implantation process on a portion of the polysilicon layer or a single-crystal silicon layer to form the first source/drain structure and the second source/drain structure, in which another portion of the polysilicon layer or a single-crystal silicon layer forms the channel layer.

In an embodiment of the present disclosure, the operation of forming the first heater and the second heater includes: forming a dielectric layer over the thin film transistor layer; patterning the dielectric layer to form a patterned dielectric layer having a first opening and a second opening, in which the first opening and the second opening respectively expose the first source/drain structure and the second source/drain structure; and forming the first heater and the second heater in the first opening and the second opening.

In an embodiment of the present disclosure, the operation of forming the phase change layer includes: forming a phase change material covering the first heater and the second heater; and patterning the phase change material to remove a portion of the phase change material to form the phase change layer.

In an embodiment of the present disclosure, the operation of forming the first heater and the second heater, and the operation of forming the phase change layer include: forming a dielectric layer over the thin film transistor layer; forming a phase change material over the dielectric layer; patterning the dielectric layer and the phase change material to form a patterned dielectric layer and the phase change layer, in which the patterned dielectric layer and the phase change layer collectively have a first opening and a second opening, and the first opening and the second opening respectively expose the first source/drain structure and the second source/drain structure; and forming the first heater and the second heater in the first opening and the second opening.

In an embodiment of the present disclosure, the operation of forming the first heater and the second heater in the first opening and the second opening includes: forming a heater material covering the phase change layer and filling the first opening and the second opening; and patterning the heater material to form the first heater and the second heater.

In an embodiment of the present disclosure, the operation of forming the first heater and the second heater in the first opening and the second opening includes: forming a metallic material covering the phase change layer and filling the first opening and the second opening; performing an annealing process to react a portion of the metallic material in the first opening and the second opening with the first source/drain structure and the second source/drain structure to form the first heater and the second heater; and removing an unreacted portion of the metallic material.

As can be seen from the above embodiments, the present disclosure provides a memory cell and a memory device including the memory cell. The present disclosure simplifies the structure and the manufacturing process of the memory cell. Compared to the prior art, the memory device of the present invention has a lower operating voltage and a higher programming and reading speed. Further, in the conventional memory device, the floating gate is easily damaged by a large operating voltage. In contrast, since the memory device of the present disclosure has a low operating voltage, it is less likely to damage the components in the device, thereby increasing the endurance of the device.

The above description will be described in detail in the following embodiments, and further explanation of the technical solutions of the present disclosure is provided.

### BRIEF DESCRIPTION OF THE DRAWINGS

The various aspects of the present disclosure can be better understood from the following detailed description and the figures. It should be noted that, according to standard practice in the industry, various features are not drawn to scale. In fact, the dimensions of multiple features can be arbitrarily increased or decreased to make the description clear.

FIG. 1 is a circuit diagram of a memory device according to some embodiments of the present disclosure.

FIG. 2 is a cross-sectional view of a memory cell according to some embodiments of the present disclosure.

FIG. 3 is a cross-sectional view of a memory cell according to other embodiments of the present disclosure.

FIG. 4 is a top view of a memory device according to some embodiments of the present disclosure.

FIGS. 5A-17A and FIGS. 5B-17B are cross-sectional views of various stages of a method of manufacturing a memory cell according to some embodiments of the present disclosure.

FIGS. 18A-23A and FIGS. 18B-23B are cross-sectional views of various stages of a method of manufacturing a memory cell according to other embodiments of the present disclosure.

### DETAILED DESCRIPTION

The following disclosure provides many different embodiments or examples for implementing different features of the subject matter provided. Specific examples of components and arrangements are described below to simplify the disclosure. These are merely examples and are not intended to limit the disclosure. For example, forming a first feature over a second feature or on a second feature in a subsequent description may include an embodiment of forming the first feature and the second feature that are in direct contact, and may also include an embodiment of forming an additional feature between the first and second features such that the first and second features are not in direct contact. In addition, in each example of the present disclosure, element reference numerals and/or letters may be repeated. This repetition is for the purpose of simplification and clarity, and is not intended to indicate the relationship between the various embodiments and/or constructions discussed.

In addition, spatially relative terms, such as “beneath”, “under”, “lower”, “over”, “upper”, and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptions used herein may likewise be interpreted accordingly.

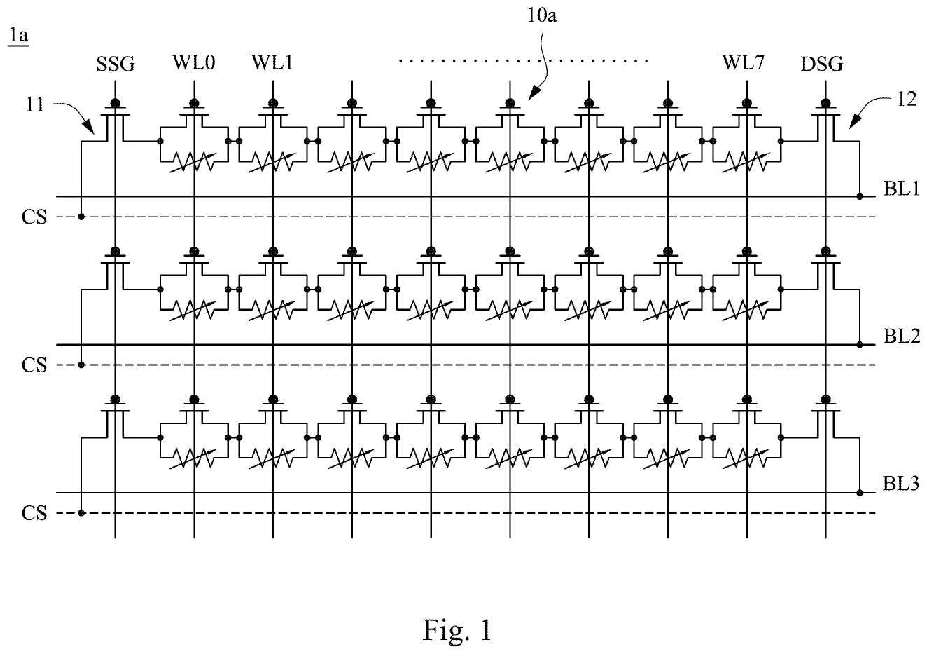

Please refer to FIG. 1. FIG. 1 is a circuit diagram of a memory device 1 a according to some embodiments of the present disclosure. As shown in FIG. 1, the memory device 1 a includes a plurality of memory cells 10a, a plurality of N-type metal oxide semiconductor (NMOS) transistors 11, 12, a plurality of word lines WL0 to WL7, and a plurality of bit lines BL1 to BL3, a plurality of source lines CS, a source control line SSG, and a drain control line DSG. The memory cell 10a includes a transistor and a resistor (1T1R) connected in parallel. The plurality of memory cells 10a are connected in series and electrically connected to the drain of the NMOS transistor 11 and the source of the NMOS transistor 12.

The source of the NMOS transistor 11 is electrically connected to one of the source lines CS, and the drain of the NMOS transistor 12 is electrically connected to one of the bit lines (e.g., BL1). The gate of the NMOS transistor 11 is electrically connected to the source control line SSG, and the gate of the NMOS transistor 12 is electrically connected to the drain control line DSG. Therefore, the voltage signals of the source control line SSG and the drain control line DSG can turn on or turn off the NMOS transistors 11, 12, thereby controlling current flow in and out of the plurality of memory cells 10a connected in series.

The transistor of each memory cell 10a includes a gate electrically connected to one of the plurality of word lines WL0 to WL7. Therefore, whether the current flows through a resistive component of the memory cell 10a can be controlled by the voltage signals of the word lines WL0 to WL7 to perform program and read on the memory cell 10a. Those will be described in detail below.

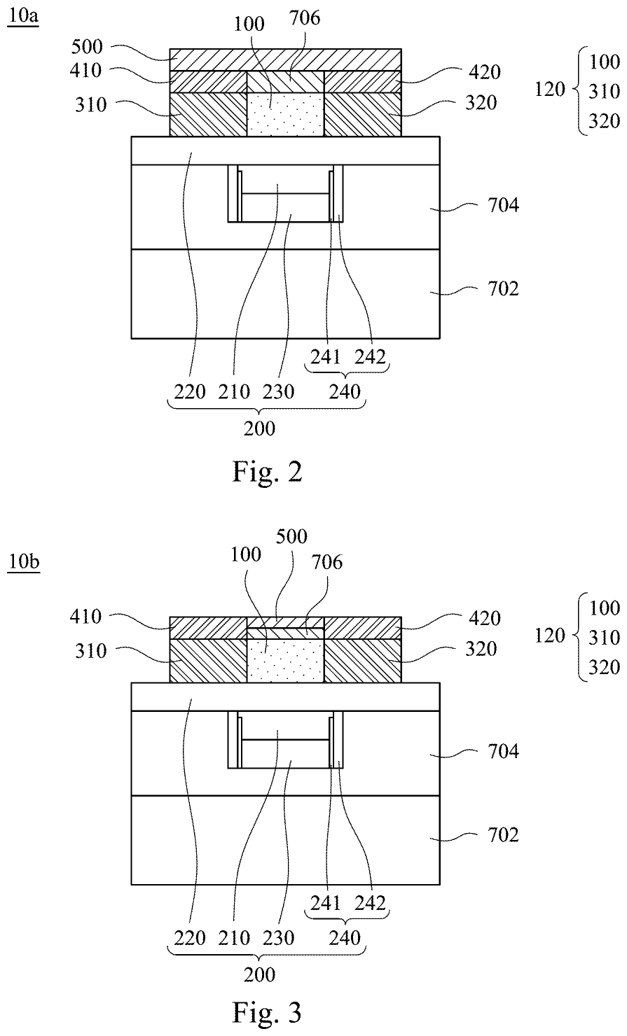

Please refer to FIG. 2. FIG. 2 is a cross-sectional view of a memory cell 10a according to some embodiments of the present disclosure. As shown in FIG. 2, the memory cell 10a includes a thin film transistor layer 120, a gate structure 200, a first heater 410, a second heater 420, and a phase change layer 500.

Specifically, in some embodiments of the present disclosure, the memory cell 10a further includes a substrate 702 and a dielectric layer 704 disposed over the substrate 702. In some embodiments, the substrate 702 includes a silicon substrate, a silicon-germanium substrate, a silicon carbide substrate, or a silicon-on-insulator (SOI) substrate, etc., but is not limited thereto. In some embodiments, the dielectric layer 704 includes oxide, nitride, oxynitride, or a combination thereof. For example, the dielectric layer 704 may be silicon oxide, silicon nitride, silicon oxynitride, or a combination thereof.

The gate structure 200 includes a gate conductive layer 210, a gate dielectric layer 220, a gate metal layer 230, and a gate spacer 240. Specifically, the gate conductive layer 210, the gate metal layer 230, and the gate spacer 240 are embedded in the dielectric layer 704. As shown in FIG. 2, the gate conductive layer 210 is disposed over the gate metal layer 230, and the gate spacer 240 is disposed over opposite sidewalls of the gate conductive layer 210 and opposite sidewalls of the gate metal layer 230. In some embodiments, the gate conductive layer 210 includes polysilicon, such as N-type doped polysilicon. In some embodiments, the gate metal layer 230 includes Ti, Ta, TiN, TaN, NiSi, or CoSi, etc., but is not limited thereto. Providing the gate metal layer 230 in contact with the gate conductive layer 210 can reduce electrical resistance loading effect of the gate, thereby improving the problem of RC (resistance-capacitance) delay.

The gate spacer 240 may be a single-layered structure or a multilayered structure. For example, in the present embodiment, the gate spacer 240 includes a first spacer 241 and a second spacer 242. The first spacer 241 is disposed over the opposite sidewalls of the gate conductive layer 210 and the opposite sidewalls of the gate metal layer 230, and the second spacer 242 is disposed over outer sidewalls of the first spacer 241. Specifically, an upper surface of the second spacer 242 is higher than an upper surface of the first spacer 241. The upper surface of the second spacer 242 is coplanar with an upper surface of the gate conductive layer 210 and is exposed outside the dielectric layer 704. In some embodiments, the gate spacer 240 includes oxide, nitride, oxynitride, or a combination thereof. For example, in one embodiment, the first spacer 241 is silicon oxide, and the second spacer 242 is silicon nitride.

The gate dielectric layer 220 covers the dielectric layer 704, the gate conductive layer 210, and the gate spacer 240. According to some embodiments, the gate dielectric layer 220 includes silicon oxide, silicon nitride or a plurality of layers of the above-mentioned materials. In other embodiments, the gate dielectric layer 220 includes a dielectric material with a high dielectric constant. For example, the gate dielectric layer 220 has a dielectric constant greater than about 7.0 and may include metal oxide or silicate of Hf, Al, Zr, La, Mg, Ba, Ti, Pb, or a combination thereof.

The thin film transistor layer 120 includes a channel layer 100 and a first source/drain structure 310 and a second source/drain structure 320 in contact with opposite sides of the channel layer 100. The channel layer 100, the first source/drain structure 310, and the second source/drain structure 320 are disposed over the gate dielectric layer 220. Specifically, the first source/drain structure 310 and the second source/drain structure 320 are disposed over opposite sides of the gate conductive layer 210, and the channel layer 100 is disposed between and in contact with the first source/drain structure 310 and the second source/drain structure 320. A width of the gate conductive layer 210 and a width of the gate metal layer 230 are slightly larger than a width of the channel layer 100 to control turn-on or turn-off of the channel layer 100. Furthermore, the channel layer 100 is completely covered by the gate dielectric layer 220 in a direction perpendicular to a projection. In some embodiments of the present disclosure, the channel layer 100 includes polysilicon and single-crystal silicon, and the first source/drain structure 310 and the second source/drain structure 320 include N-doped polysilicon and single-crystal silicon.

The first heater 410 and the second heater 420 are respectively disposed over the first source/drain structure 310 and the second source/drain structure 320. In some embodiments of the present disclosure, the memory cell 10a further includes a dielectric layer 706 disposed between the first heater 410 and the second heater 420. Specifically, an upper surface of the first heater 410, an upper surface of the second heater 420, and an upper surface of the dielectric layer 706 are coplanar, as shown in FIG. 2. In some embodiments, the first heater 410 and the second heater 420 include titanium, titanium nitride, tantalum nitride, titanium aluminum nitride, tantalum aluminum nitride, or a combination thereof. Alternatively, in other embodiments, the first heater 410 and the second heater 420 include cobalt silicide, nickel silicide, titanium silicide, platinum silicide, or other metal silicides. In some embodiments, the dielectric layer 706 includes oxide, nitride, oxynitride, or a combination thereof.

The phase change layer 500 is disposed over the channel layer 100 and in contact with the first heater 410 and the second heater 420. Specifically, the phase change layer 500 is disposed over the first heater 410, the second heater 420, and the dielectric layer 706, and bottoms of both ends of the phase change layer 500 are in contact with the first heater 410 and the second heater 420. As shown in FIG. 2, the phase change layer 500 is separated from the channel layer 100 by the dielectric layer 706, so that metal ions of the phase change layer 500 can be prevented from diffusing or penetrating into the channel layer 100 to cause contamination. In some embodiments, the phase change layer 500 includes germanium-stibium-tellurium (Ge₂Sb₂Te₅, Ge₃Sb₆Te₅, GST), nitrogen-doped germanium-stibium-tellurium (nitrogen-doped Ge₂Sb₂Te₅), antimony telluride (Sb₂Te), germanium-antimony (GeSb), indium-doped antimony telluride (In-doped Sb₂Te), or a combination thereof.

As described above, it is possible to control whether the current flows through the resistive component of the memory cell 10a by controlling the voltage signals of the word lines for programming and reading. Specifically, when a suitable bias voltage is applied to the gate conductive layer 210, the channel layer 100 near the surface of the gate dielectric layer is turned on, so that the electrical resistance value of the channel layer 100 is lower than that of the phase change layer 500, so the current can flow from the first source/drain structure 310 to the second source/drain structure 320 through the channel layer 100. On the contrary, when the suitable bias voltage is not applied to the gate conductive layer 210, the channel layer 100 is not turned on, so that the electrical resistance value of the channel layer 100 is much higher than that of the phase change layer 500, so the current will flow from the first source/drain structure 310 to the second source/drain structure 320 through the first heater 410, the phase change layer 500, and the second heater 420. Accordingly, during programming, the phase change layer 500 is heated by ohmic heating and is converted between the crystalline phase and the amorphous phase by the current values and the speed of cooling of the phase change layer to store different values of data.

Please refer to FIG. 3. FIG. 3 is a cross-sectional view of a memory cell 10b according to other embodiments of the present disclosure. It should be noted that as shown in FIG. 3, the same or similar elements as those in FIG. 2 are given the same reference numerals and the description will be omitted. The memory cell 10b of FIG. 3 is similar to the memory cell 10a of FIG. 2, and the difference is that an upper surface of the dielectric layer 706 of the memory cell 10b is lower than an upper surface of the first heater 410 and an upper surface of the second heater 420. The phase change layer 500 is disposed between the first heater 410 and the second heater 420, and sidewalls of both ends of the phase change layer 500 are in contact with the first heater 410 and the second heater 420. Further, as shown in FIG. 3, the upper surface of the first heater 410, the upper surface of the second heater 420, and the upper surface of the phase change layer 500 are coplanar. However, it should be understood that in some embodiments, the upper surface of the first heater 410, the upper surface of the second heater 420, and the upper surface of the phase change layer 500 may be non-coplanar.

It is worth mentioning that a contact area between the phase change layer 500 and the first heater 410 or the second heater 420 can be reduced by disposing the phase change layer 500 between the first heater 410 and the second heater 420. Therefore, the current density can be increased to increase the phase transition rate of the phase change layer 500 and reduce power consumption.

Further, compared to the phase change layer 500 disposed over the first heater 410 and the second heater 420 (as shown in FIG. 2), the phase change layer 500 disposed between the first heater 410 and the second heater 420 (as shown in FIG. 3) can improve a problem of data read errors. Specifically, the current path through the phase change layer 500 of FIG. 2 (or referred to as a switch region) is larger than that of FIG. 3. Therefore, when programming is performed, a variation in the operating voltage may affect the size of the switching region of the phase change layer 500, which easily causes the problem of data reading errors. Compared to this, the phase change layer 500 of FIG. 3 is disposed between the first heater 410 and the second heater 420, and thus the current path through the phase change layer 500 is limited thereto. Therefore, when programming is performed, a variation in the operating voltage does not significantly affect the size of the switching region of the phase change layer 500, and thus the problem of data reading errors can be improved.

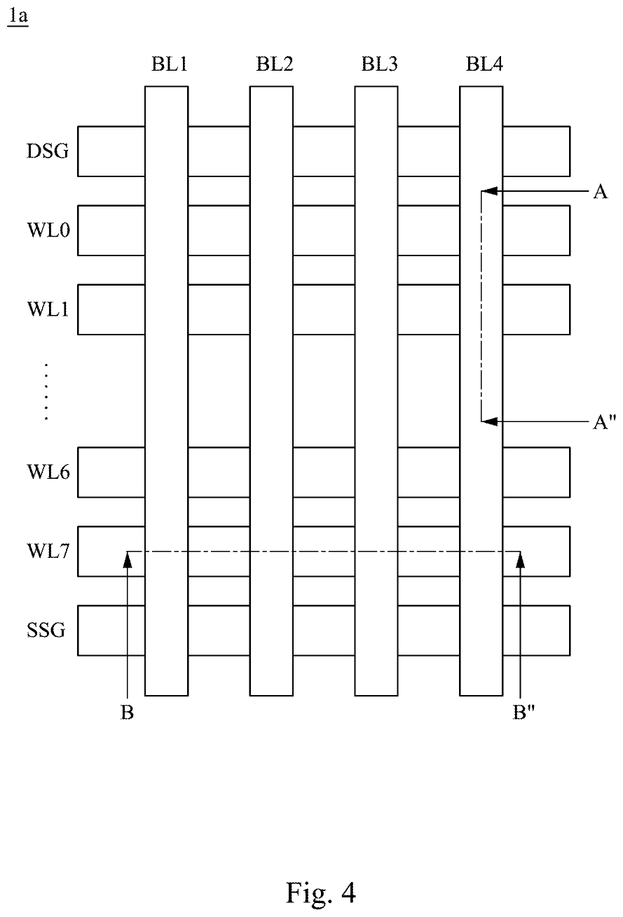

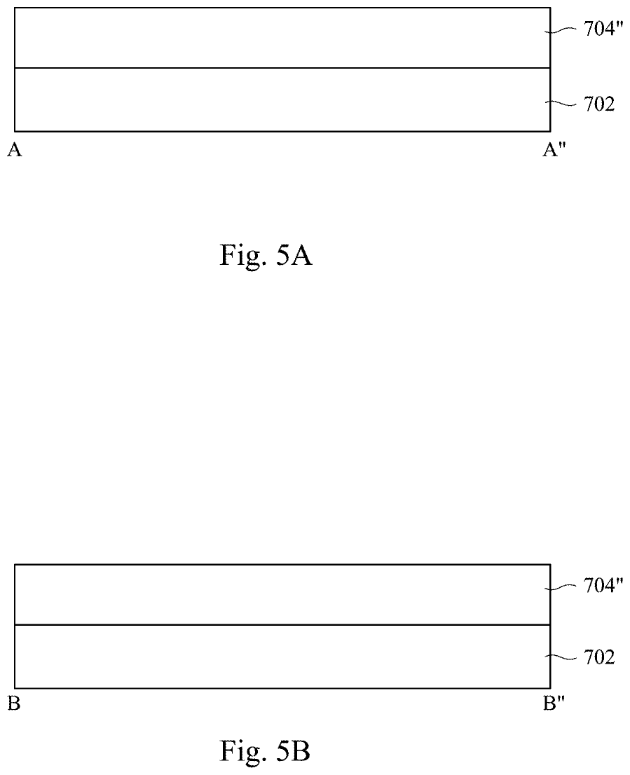

FIG. 4 is a top view of a memory device 1 a according to some embodiments of the present disclosure. FIGS. 5A-17A are cross-sectional views of various stages of a method of manufacturing the memory device 1 a taken along line A-A″ of FIG. 4 according to some embodiments of the present disclosure, and FIGS. 5B-17B are cross-sectional views of various stages taken along line B-B″ of FIG. 4.

Referring to FIGS. 5A and 5B, a substrate 702 is firstly provided, and a dielectric layer 704″ is formed over the substrate 702. In some embodiments of the present disclosure, the dielectric layer 704″ is formed by using chemical vapor deposition or other suitable thin film deposition technique.

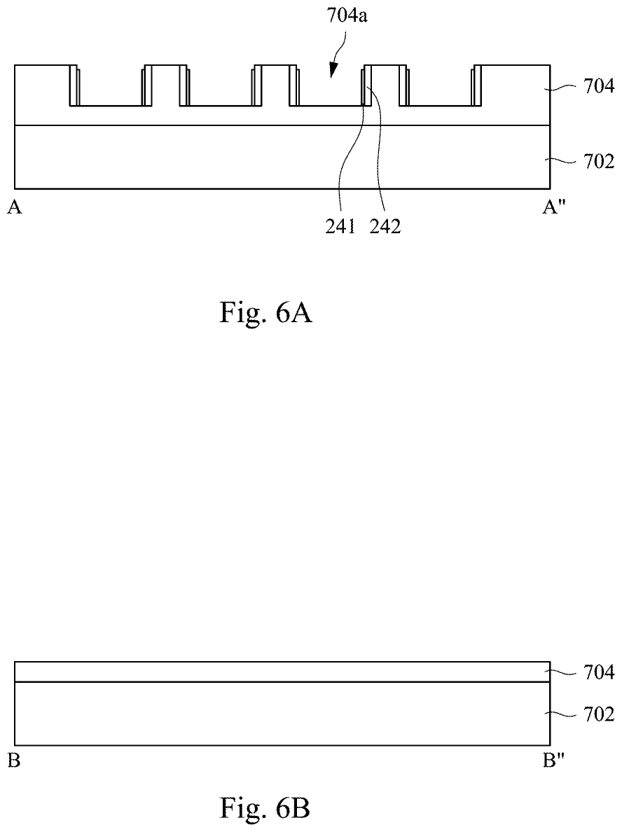

Next, as shown in FIGS. 6A and 6B, the dielectric layer 704″ is patterned to form a patterned dielectric layer 704 having a plurality of openings 704a. In some embodiments of the present disclosure, the openings 704a are formed by using lithography and etching processes, a laser drilling process, or other suitable processes. Next, a first spacer 241 and a second spacer 242 are formed over a sidewall of each opening 704a. For example, a dielectric material, such as silicon oxide, silicon nitride or silicon oxynitride, is deposited over the dielectric layer 704 and the sidewall and a lower surface of each opening 704a by using physical vapor deposition, chemical vapor deposition, atomic layer deposition, etc. Subsequently, the dielectric material over the dielectric layer 704 and the dielectric material over the lower surface of the opening 704a are anisotropically removed to form the first spacer 241 and the second spacer 242.

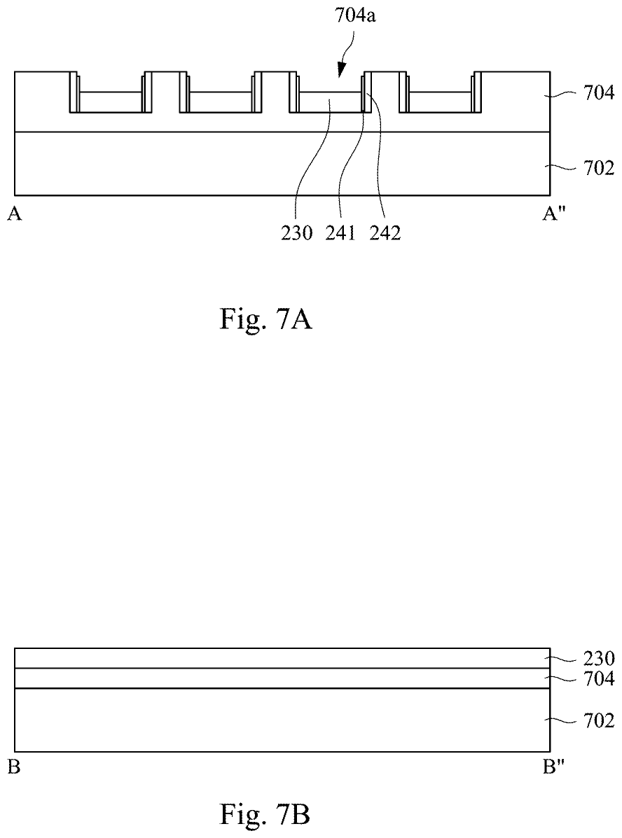

Please refer to FIGS. 7A and 7B. A gate metal layer 230 is formed in each opening 704a. For example, a material, such as Ti, Ta, TiN, TaN, NiSi or CoSi, is deposited over the dielectric layer 704 and in each opening 704a by using physical vapor deposition, chemical vapor deposition, atomic layer deposition or the like. Next, a patterned photoresist layer (not shown) is formed over the dielectric layer 704, and the material is etched by using the patterned photoresist layer as an etch mask to form the gate metal layer 230.

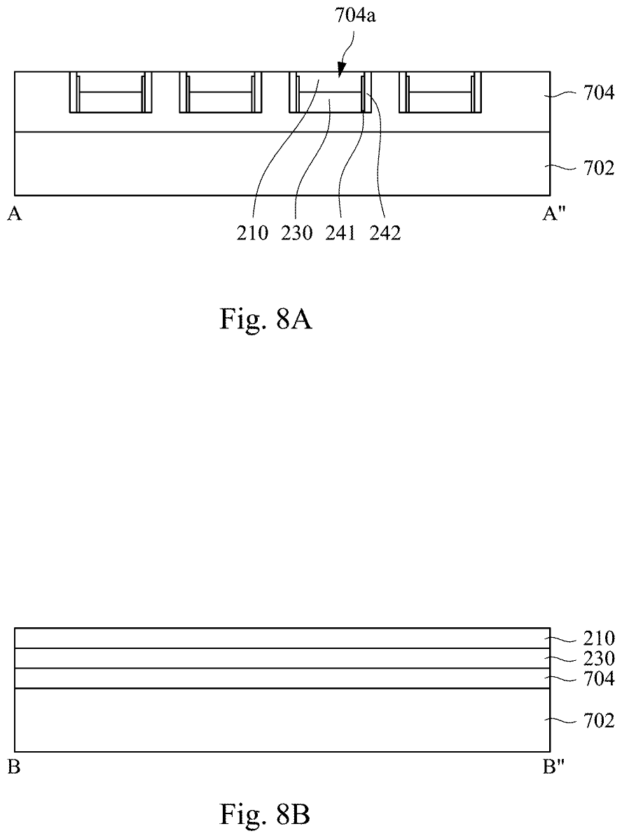

After the gate metal layer 230 is formed, as shown in FIGS. 8A and 8B, the gate conductive layer 210 is formed in a remaining portion of each opening 704a. In some embodiments of the present disclosure, polysilicon is deposited over the dielectric layer 704 and in the remaining portion of each opening 704a by using physical vapor deposition, chemical vapor deposition, atomic layer deposition, and the like. Subsequently, an excess of polysilicon is removed by using a chemical mechanical polishing (CMP) process to form the gate conductive layer 210. After the chemical mechanical polishing process, an upper surface of the gate conductive layer 210, an upper surface of the second spacer 242, and an upper surface of the dielectric layer 704 are coplanar.

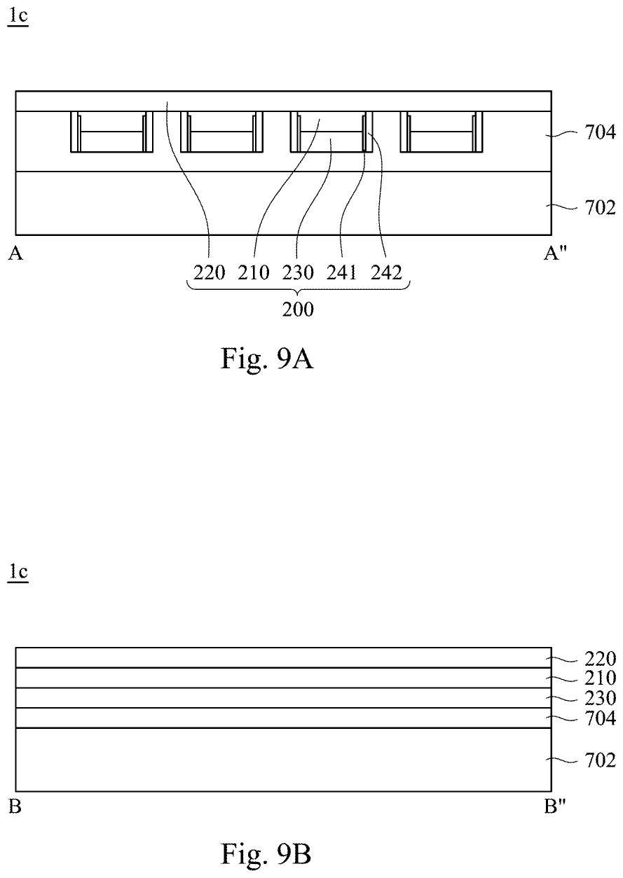

Next, as shown in FIGS. 9A and 9B, a gate dielectric layer 220 is formed covering the gate conductive layer 210, the second spacer 242, and the dielectric layer 704, thereby forming a precursor structure 1c. For example, a material, such as silicon oxide or silicon nitride, is deposited over the gate conductive layer 210, the second spacer 242, and the dielectric layer 704 by using physical vapor deposition, chemical vapor deposition, atomic layer deposition, or the like to form the gate dielectric layer 220.

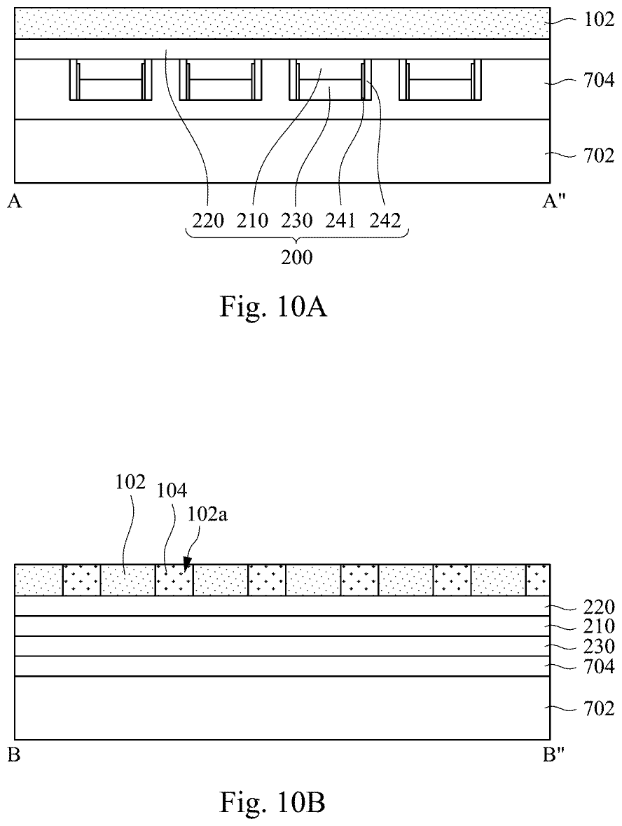

Please refer to FIGS. 10A and 10B. An amorphous silicon layer is formed over the gate dielectric layer 220. For example, the amorphous silicon layer is formed over the gate dielectric layer 220 by using sputtering, physical vapor deposition, chemical vapor deposition, atomic layer deposition, or the like. Next, an annealing process is performed to crystallize the amorphous silicon layer to form a polysilicon layer or a single-crystal silicon layer. Preferably, the above annealing process is performed under an argon atmosphere.

Next, the polysilicon layer or the single-crystal silicon layer is patterned to form a patterned polysilicon layer or a single-crystal silicon layer 102 having a plurality of trenches 102a (as shown in FIG. 10B). For example, a patterned photoresist layer (not shown) is formed over the polysilicon layer or the single-crystal silicon layer, and the polysilicon layer or the single-crystal silicon layer is etched by using the patterned photoresist layer as an etch mask to form the trenches 102a. Subsequently, the patterned photoresist layer is removed. Next, a shallow trench isolation structure 104 is formed in each trench 102a. For example, a dielectric material, such as oxide, nitride, or oxynitride, is deposited over the patterned polysilicon layer or the single-crystal silicon layer 102 and in each trench 102a by using physical vapor deposition, chemical vapor deposition, atomic layer deposition, or the like. Subsequently, an excess of the dielectric material is removed by using a chemical mechanical polishing process to form the shallow trench isolation structure 104. After the chemical mechanical polishing process, an upper surface of the formed shallow trench isolation structure 104 is coplanar with an upper surface of the patterned polysilicon layer or the single-crystal silicon layer 102.

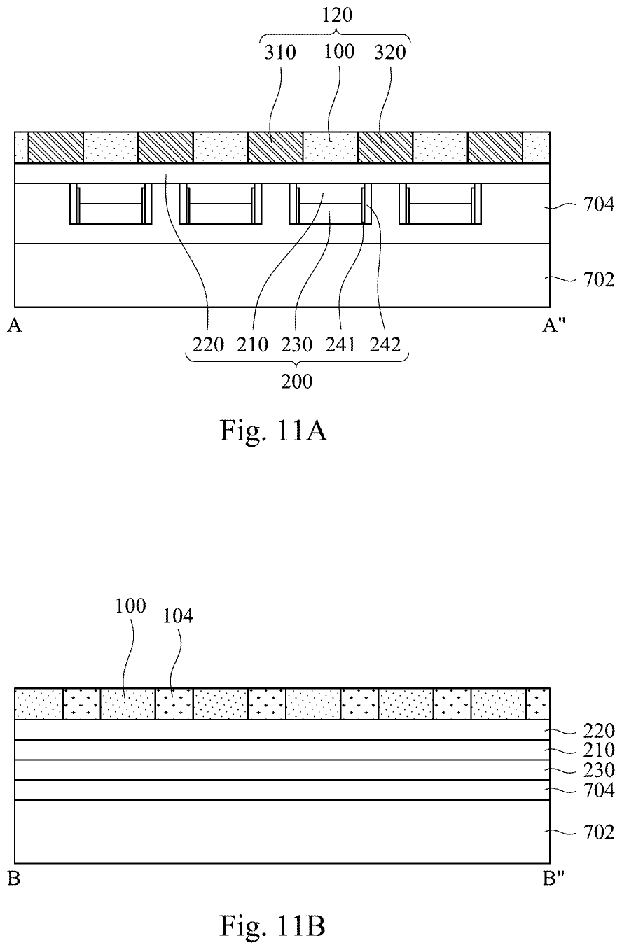

After the shallow trench isolation structure 104 is formed, as shown in FIGS. 11A and 11B, an implantation process is performed on a portion of the patterned polysilicon layer or the single-crystal silicon layer 102 to form a thin film transistor layer 120 including a plurality of source/drain structures (e.g., a first source/drain structure 310 and a second source/drain structure 320) and a channel layer 100. Specifically, as shown in FIG. 11A, the formed first source/drain structure 310 and the second source/drain structure 320 are located at opposite sides of one of the plurality of gate conductive layers 210 and partially overlapped with the gate conductive layer 210. The channel layer 100 is located between and in contact with the first source/drain structure 310 and the second source/drain structure 320. Furthermore, the channel layer 100 is completely covered by the gate dielectric layer 220 in a direction perpendicular to a projection.

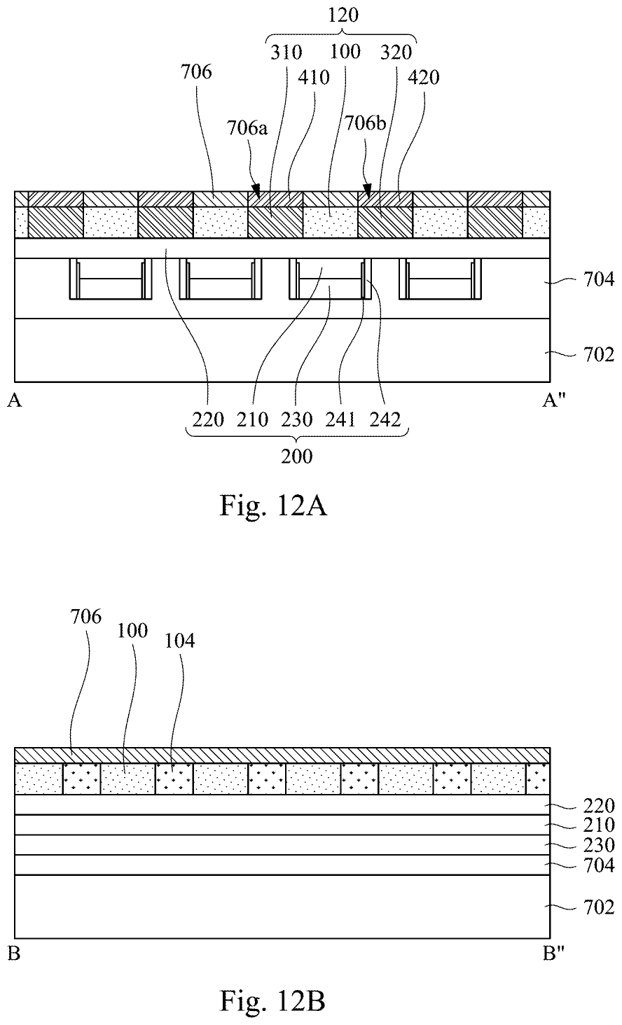

Next, as shown in FIGS. 12A and 12B, a patterned dielectric layer 706 having a plurality of openings (e.g., a first opening 706a and a second opening 706b) is formed over the channel layer 100 of the thin film transistor layer 120. For example, a dielectric material, such as oxide, nitride, and oxynitride, is deposited over the thin film transistor layer 120 by using physical vapor deposition, chemical vapor deposition, atomic layer deposition, or the like. Next, the dielectric material is patterned to form the patterned dielectric layer 706. The method of patterning is, for example, forming a patterned photoresist layer (not shown) over the dielectric material, and etching the dielectric material by using the patterned photoresist layer as an etch mask to form the patterned dielectric layer 706. Subsequently, the patterned photoresist layer is removed. As shown in FIG. 12A, the first opening 706a and the second opening 706b expose the first source/drain structure 310 and the second source/drain structure 320, respectively.

Next, a plurality of heaters (e.g., a first heater 410 and a second heater 420) are formed in the plurality of openings (e.g., the first opening 706a and the second opening 706b) of the patterned dielectric layer 706. For example, a heater material, such as titanium, titanium nitride, tantalum nitride, titanium aluminum nitride, or tantalum aluminum nitride, is deposited over the patterned dielectric layer 706 and in the plurality of openings of patterned dielectric layer 706 by using physical vapor deposition, chemical vapor deposition, atomic layer deposition, etc. Subsequently, an excess of the heater material is removed by using a chemical mechanical polishing process to form the plurality of heaters. After the chemical mechanical polishing process, an upper surface of each of the formed heaters (e.g., the first heater 410 and the second heater 420) is coplanar with an upper surface of the patterned dielectric layer 706.

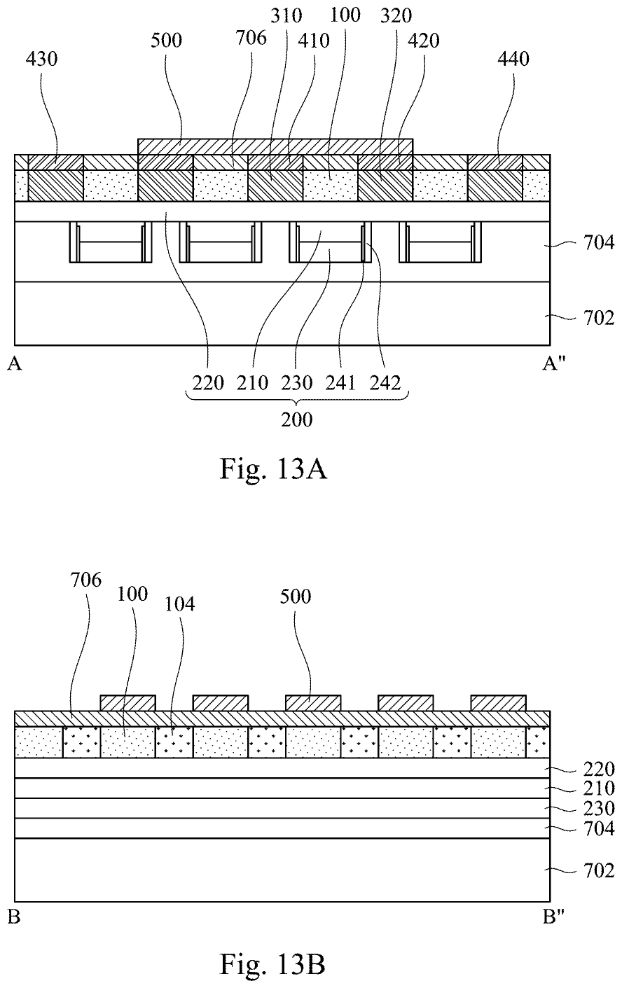

Please refer to FIGS. 13A and 13B. A phase change layer 500 is formed over the plurality of heaters (e.g., the first heater 410 and the second heater 420) and the patterned dielectric layer 706. For example, a phase change material, such as germanium-stibium-tellurium, nitrogen-doped germanium-stibium-tellurium, antimony telluride, germanium-antimony, or indium-doped antimony telluride, is deposited covering the patterned dielectric layer 706 and each of the heaters (e.g., the first heater 410 and the second heater 420) by using physical vapor deposition, chemical vapor deposition, atomic layer deposition, etc. Next, the phase change material is patterned to form the phase change layer 500. The method of patterning is, for example, forming a patterned photoresist layer (not shown) over the phase change material, and etching the phase change material by using the patterned photoresist layer as an etch mask to form the phase change layer 500. Subsequently, the patterned photoresist layer is removed. As shown in FIG. 13A, the phase change layer 500 is across and in contact with the plurality of heaters. It should be understood that after the phase change material is patterned, the leftmost heater 430 (or called as the conductive contact 430) and the rightmost heater 440 (or called as the conductive contact 440) are exposed.

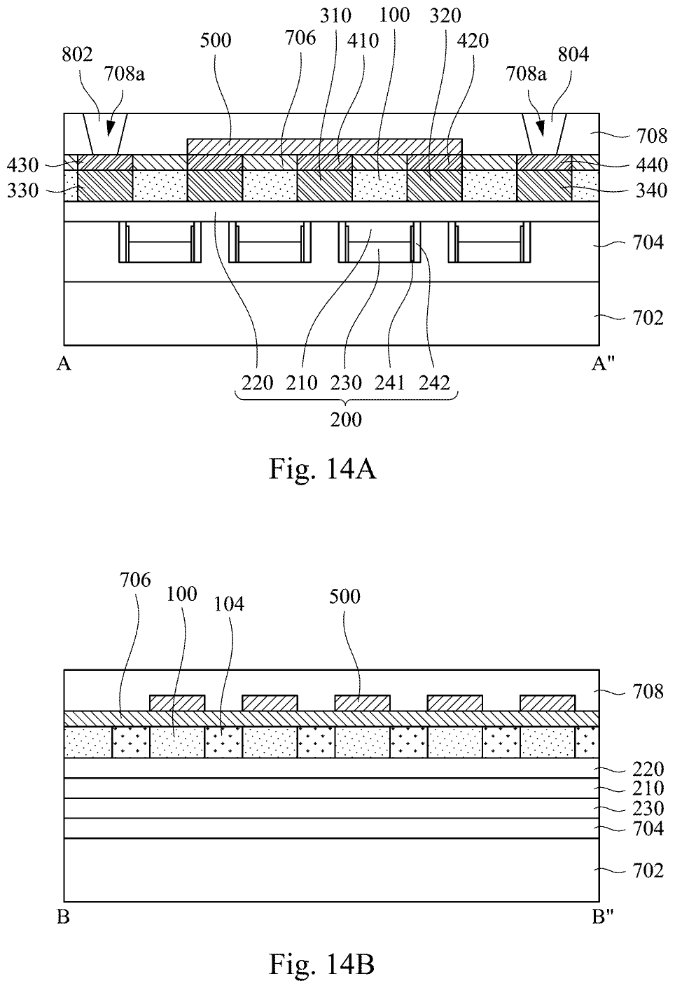

After the phase change layer 500 is formed, as shown in FIGS. 14A and 14B, a first interlayer dielectric layer (ILD) 708 is formed covering the conductive contacts 430, 440, the patterned dielectric layer 706, and the phase change layer 500. The first interlayer dielectric layer 708 has a plurality of openings 708a exposing the conductive contact 430 and the conductive contact 440. In some embodiments of the present disclosure, a dielectric material, such as oxide, nitride, or oxynitride, is deposited over the conductive contacts 430, 440, the patterned dielectric layer 706, and the phase change layer 500 by using chemical vapor deposition or other suitable thin film deposition technique to form the first interlayer dielectric layer 708. Next, the openings 708a through the first interlayer dielectric layer 708 are formed by using lithography and etching processes, a laser drilling process, or other suitable processes.

Next, conductive plugs 802, 804 are formed in the openings 708a of the first interlayer dielectric layer 708. For example, a metallic material, such as titanium, tantalum, tungsten, aluminum, copper, molybdenum, platinum, or titanium nitride, is deposited over the first interlayer dielectric layer 708 and in the openings 708a by using physical vapor deposition, chemical vapor deposition, atomic layer deposition, or the like. Subsequently, an excess of the metallic material is removed by using a chemical mechanical polishing process to form the conductive plugs 802, 804. After the chemical mechanical polishing process, an upper surface of the formed conductive plug 802, an upper surface of the conductive plug 804, and an upper surface of the first interlayer dielectric layer 708 are coplanar. Subsequently, a source line (not shown) may be formed to be in contact with the conductive plug 804, such that the source line is electrically connected to the rightmost source/drain structure 340 through the conductive plug 804 and the conductive contact 440.

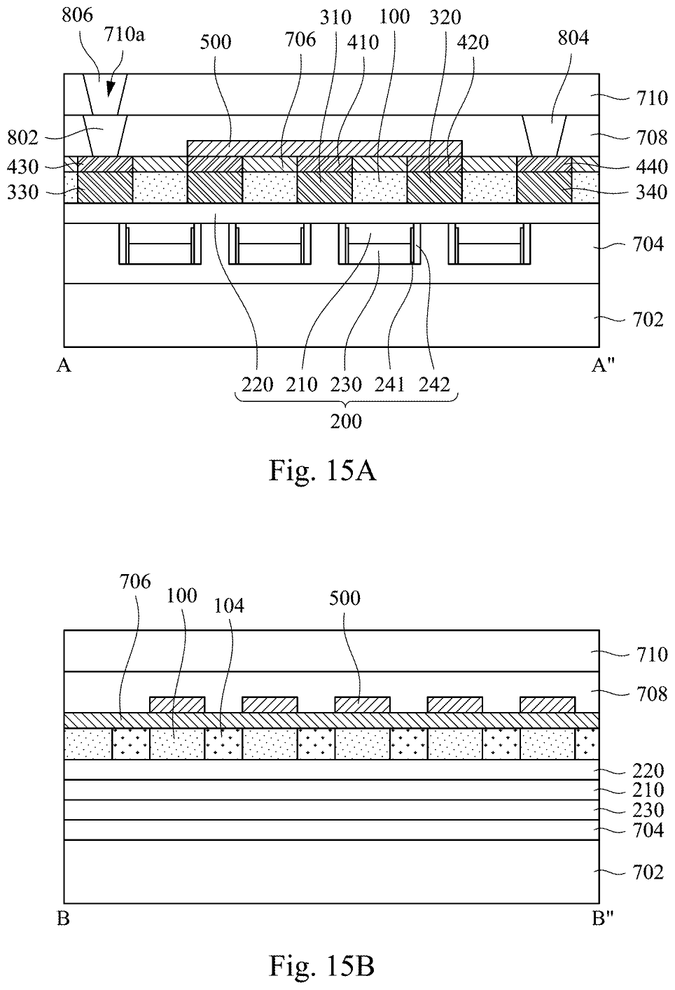

Next, as shown in FIGS. 15A and 15B, a second interlayer dielectric layer 710 is formed covering the conductive plug 802, the conductive plug 804, and the first interlayer dielectric layer 708. The second interlayer dielectric layer 710 has an opening 710a exposing the conductive plug 802. In some embodiments of the present disclosure, a dielectric material, such as oxide, nitride or oxynitride, is deposited over the conductive plug 802, the conductive plug 804, and the first interlayer dielectric layer 708 by using chemical vapor deposition or other suitable thin film deposition technique. Next, an opening 710a through the second interlayer dielectric layer 710 is formed by using lithography and etching processes, a laser drilling process, or other suitable processes.

Next, a conductive plug 806 is formed in the opening 710a of the second interlayer dielectric layer 710. For example, a metallic material, such as titanium, tantalum, tungsten, aluminum, copper, molybdenum, platinum, or titanium nitride, is deposited over the second interlayer dielectric layer 710 and in the opening 710a by using physical vapor deposition, chemical vapor deposition, atomic layer deposition, or the like. Subsequently, an excess of the metallic material is removed by using a chemical mechanical polishing process to form the conductive plug 806. After the chemical mechanical polishing process, an upper surface of the formed conductive plug 806 is coplanar with an upper surface of the second interlayer dielectric layer 710.

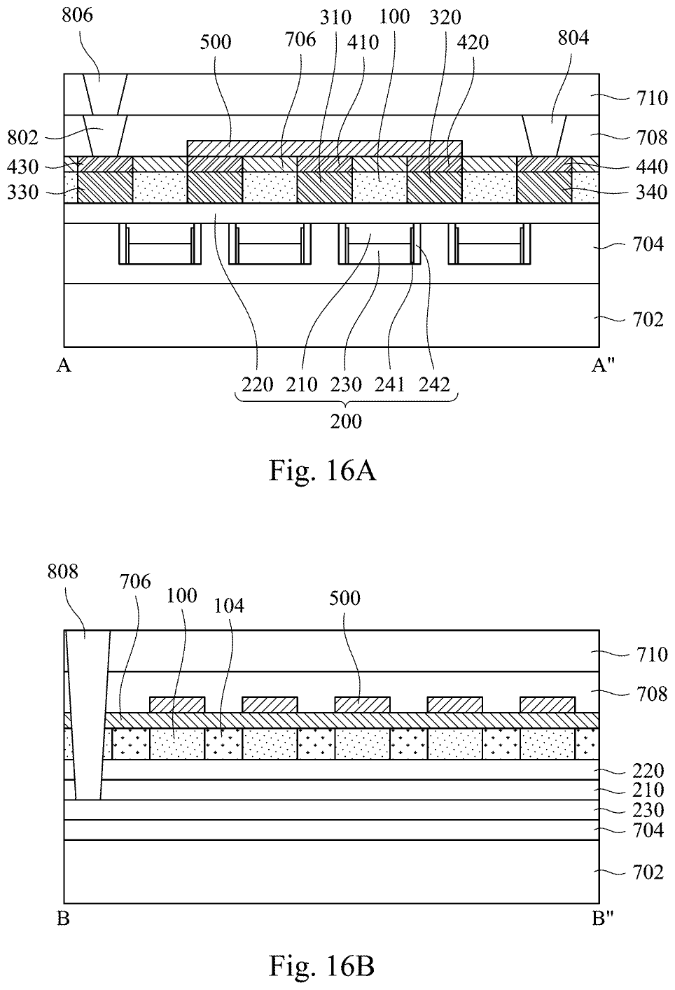

Please refer to FIGS. 16A and 16B. A conductive plug 808 (as shown in FIG. 16B) is formed through the first interlayer dielectric layer 708, the second interlayer dielectric layer 710, the patterned dielectric layer 706, the channel layer 100, the gate dielectric layer 220, and the gate conductive layer 210, and the conductive plug 808 is in contact with the gate metal layer 230. For example, openings through the above-mentioned layers are formed by using lithography and etching processes, a laser drilling process, or other suitable processes. Next, a metallic material, such as titanium, tantalum, tungsten, aluminum, copper, molybdenum, platinum, or titanium nitride, is deposited over the second interlayer dielectric layer 710 and in the openings by using physical vapor deposition, chemical vapor deposition, atomic layer deposition, or the like. Subsequently, an excess of the metallic material is removed using a chemical mechanical polishing process to form the conductive plug 808. After the chemical mechanical polishing process, an upper surface of the formed conductive plug 808 is coplanar with an upper surface of the second interlayer dielectric layer 710.

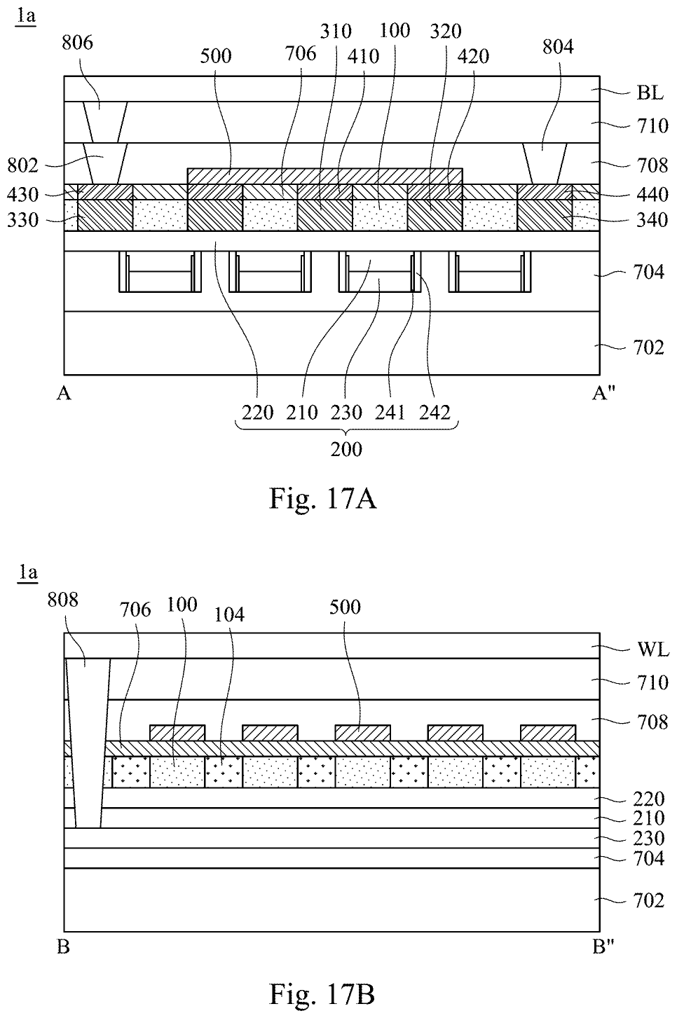

After the conductive plug 808 is formed, as shown in FIGS. 17A and 17B, a bit line BL and a word line WL are formed over the second interlayer dielectric layer 710 to form the memory device 1a. For example, a conductive material, such as titanium, tantalum, tungsten, aluminum, copper, titanium or tantalum nitride, is deposited covering the second interlayer dielectric layer 710 by using physical vapor deposition, chemical vapor deposition, atomic layer deposition or the like. Next, the conductive material is patterned to form the bit line BL and the word line WL. The method of patterning is, for example, forming a patterned photoresist layer (not shown) over the conductive material, and etching the conductive material by using the patterned photoresist layer as an etch mask to form the bit line BL and the word line WL. Subsequently, the patterned photoresist layer is removed.

As shown in FIG. 17A, the bit line BL is in contact with the conductive plug 806, so that the bit line BL can be electrically connected to the leftmost source/drain structure 330 through the conductive plug 806, the conductive plug 802, and the conductive contact 430. As shown in FIG. 17B, the word line WL is in contact with the conductive plug 808, such that the word line WL can be electrically connected to the gate conductive layer 210 and the gate metal layer 230 through the conductive plug 808.

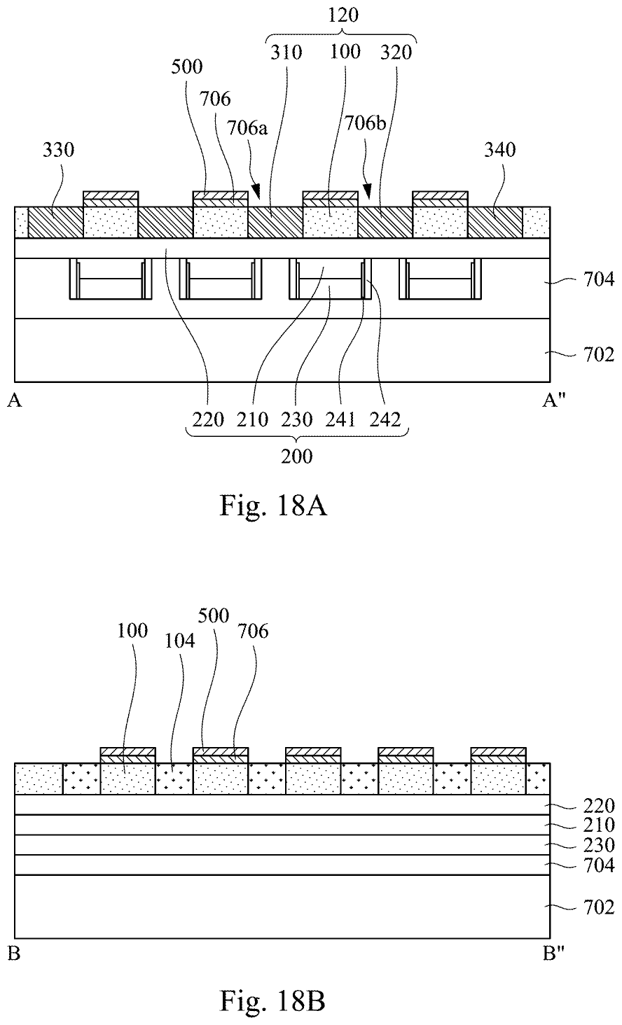

FIGS. 18A-23A are cross-sectional views of various stages of a method of manufacturing the memory device 1b taken along line A-A″ of FIG. 4 according to other embodiments of the present disclosure. FIGS. 18B-23B are cross-sectional views of various stages of a method of manufacturing the memory device 1b taken along line B-B″ of FIG. 4.

FIGS. 18A and 18B are continued from FIGS. 11A and 11B, a patterned dielectric layer 706 is formed over the channel layer 100 of the thin film transistor layer 120, and a phase change layer 500 is formed over the patterned dielectric layer 706. For example, a dielectric material, such as oxide, nitride, or oxynitrid, is deposited by using physical vapor deposition, chemical vapor deposition, atomic layer deposition, or the like to form a dielectric layer covering the thin film transistor layer 120. Next, a phase change material is deposited over the dielectric layer by using physical vapor deposition, chemical vapor deposition, atomic layer deposition or the like. Subsequently, the dielectric layer and the phase change material are patterned to form the patterned dielectric layer 706 and the phase change layer 500. As shown in FIG. 18A, the patterned dielectric layer 706 and the phase change layer 500 collectively have a plurality of openings (e.g., a first opening 706a and a second opening 706b). Each of the openings exposes the corresponding source/drain structure.

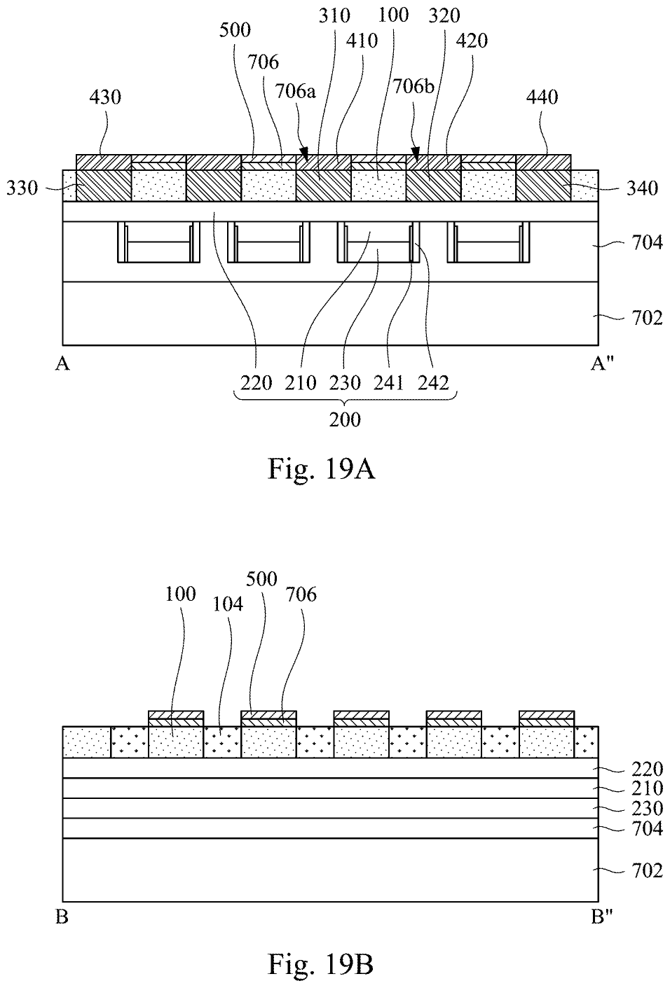

Next, as shown in FIGS. 19A and 19B, a plurality of heaters (e.g., a first heater 410 and a second heater 420) are formed in the openings (e.g., the first opening 706a and the second opening 706b).

The manner of forming the heater, for example, a heater material, such as titanium, titanium nitride, tantalum nitride, titanium aluminum nitride, or tantalum aluminum nitride, is deposited over the phase change layer 500 and filling the plurality of openings (e.g., the first opening 706a and the second opening 706b) of the phase change layer 500 by using physical vapor deposition, chemical vapor deposition, atomic layer deposition, etc. Next, the heater material is patterned to form the heaters (e.g., the first heater 410 and the second heater 420). For example, a patterned photoresist layer (not shown) is formed over the heater material, and the heater material is etched by using the patterned photoresist layer as an etch mask to form the heaters. Subsequently, the patterned photoresist layer is removed.

Alternatively, the heater is formed by depositing a metallic material, such as cobalt, nickel, titanium or platinum, over the phase change layer 500 and filling the plurality of openings (e.g., the first opening 706a and the second opening 706b) of the phase change layer 500 by using physical vapor deposition, chemical vapor deposition, atomic layer deposition or the like. Next, an annealing process is performed to cause the metallic material in the openings react with silicon of the source/drain structures (e.g., the first source/drain structure 310 and the second source/drain structure 320) therebeneath to form a metal silicide as the heater. Subsequently, an etching process is performed to remove the unreacted metallic material. It is worth mentioning that, compared with the above-mentioned method of depositing and patterning the metallic material to form the each heater, the method of depositing the metallic material and performing the annealing process to form the each heater can save one exposure and development step, and therefore has the advantage of lower cost.

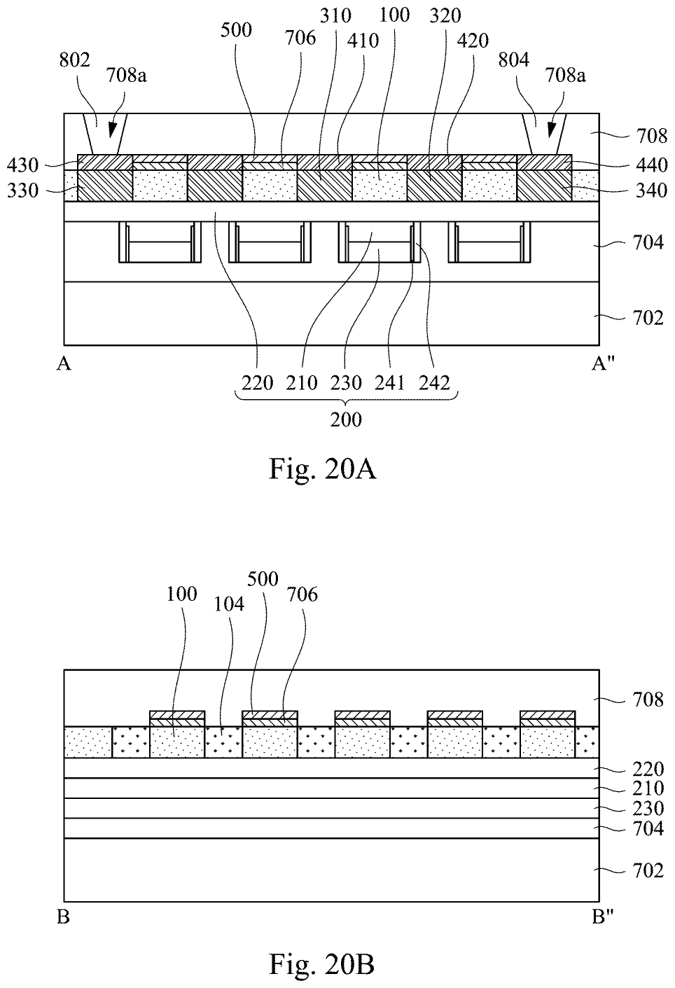

As shown in FIGS. 20A and 20B, a first interlayer dielectric layer 708 is formed covering the heaters (e.g., the first heater 410 and the second heater 420), the conductive contacts 430, 440, the channel layer 100, and the phase change layer 500. The first interlayer dielectric layer 708 has a plurality of openings 708a exposing the conductive contact 430 and the conductive contact 440. Next, conductive plugs 802, 804 are formed in the openings 708a of the first interlayer dielectric layer 708. It should be understood that the method of forming the first interlayer dielectric layer 708 and the conductive plugs 802, 804 can be referred to FIGS. 14A and 14B and the related paragraphs above, and those are not described herein again. As shown in FIG. 20A, an upper surface of the formed conductive plug 802, an upper surface of the conductive plug 804, and an upper surface of the first interlayer dielectric layer 708 are coplanar. Thereafter, a source line (not shown) may be formed to be in contact with the conductive plug 804, such that the source line is electrically connected to the rightmost source/drain structure 340 through the conductive plug 804 and the conductive contact 440.

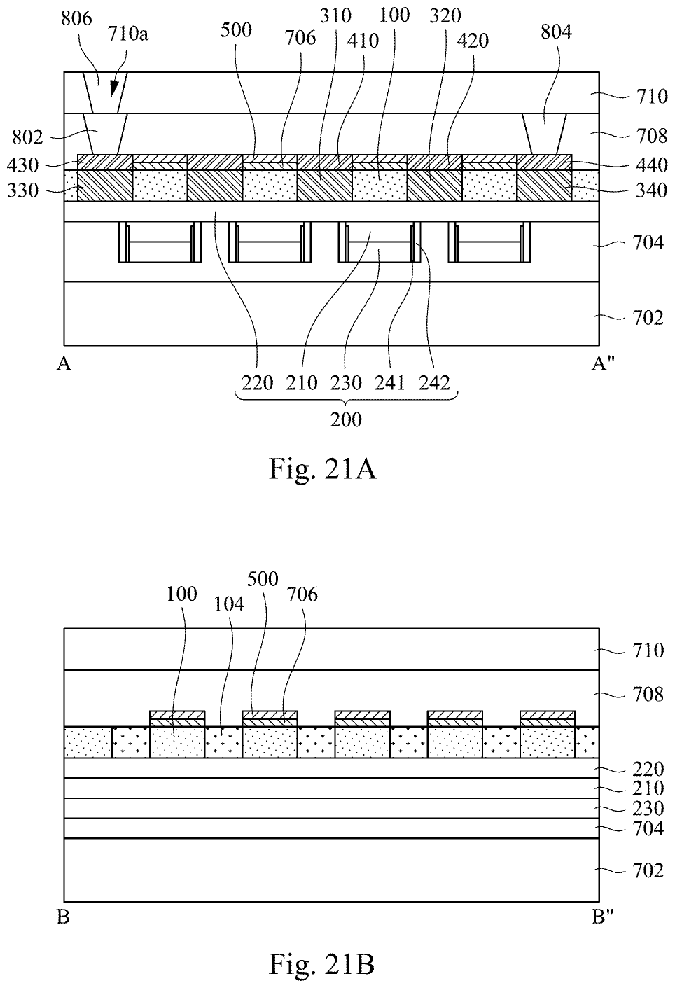

Next, as shown in FIGS. 21A and 21B, a second interlayer dielectric layer 710 is formed covering the conductive plug 802, the conductive plug 804, and the first interlayer dielectric layer 708. The second interlayer dielectric layer 710 has an opening 710a exposing the conductive plug 802. Next, a conductive plug 806 is formed in the opening 710a of the second interlayer dielectric layer 710. It should be understood that the method of forming the second interlayer dielectric layer 710 and the conductive plug 806 can be referred to FIGS. 15A and 15B and the related paragraphs above, and those are not described herein again. As shown in FIG. 21A, an upper surface of the formed conductive plug 806 is coplanar with an upper surface of the second interlayer dielectric layer 710.

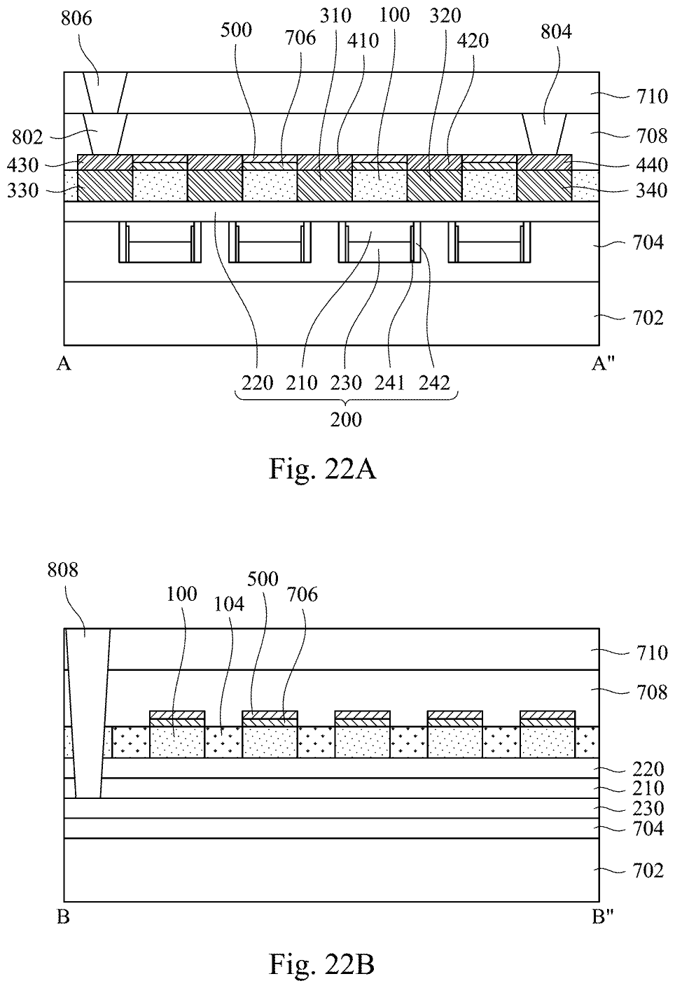

Please refer to FIGS. 22A and 22B. A conductive plug 808 (shown in FIG. 22B) is formed through the first interlayer dielectric layer 708, the second interlayer dielectric layer 710, the channel layer 100, the gate dielectric layer 220, and the gate conductive layer 210, such that the conductive plug 808 is in direct contact with the gate metal layer 230. It should be understood that the method of forming the conductive plug 808 can be referred to FIGS. 16A and 16B and the related paragraphs above, and those are not described herein again. As shown in FIG. 22B, an upper surface of the formed conductive plug 808 is coplanar with an upper surface of the second interlayer dielectric layer 710.

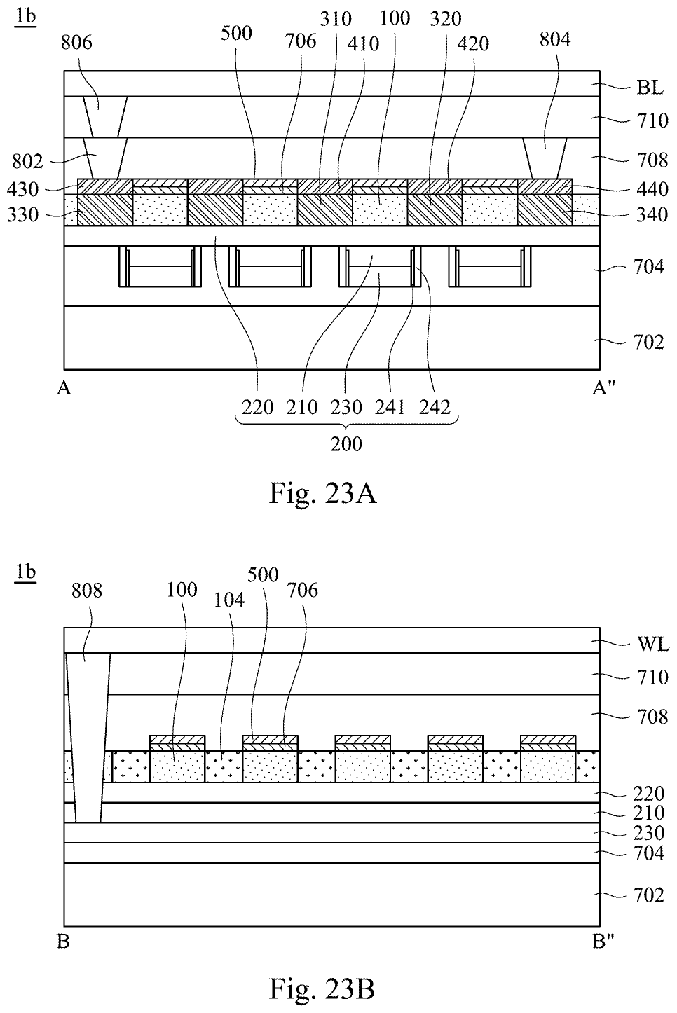

After the conductive plug 808 is formed, as shown in FIGS. 23A and 23B, a bit line BL and a word line WL are formed over the second interlayer dielectric layer 710 to form the memory device 1 b. As shown in FIG. 23A, the bit line BL is in contact with the conductive plug 806, so that the bit line BL can be electrically connected to the leftmost source/drain structure 330 through the conductive plug 806, the conductive plug 802, and the conductive contact 430. As shown in FIG. 23B, the word line WL is in contact with the conductive plug 808, such that the word line WL can be electrically connected to the gate conductive layer 210 and the gate metal layer 230 through the conductive plug 808.

As can be seen from the above embodiments of the present disclosure, the present disclosure simplifies the structure and the manufacturing process of the memory cell. Compared to the prior art, the memory device of the present disclosure has a lower operating voltage and a higher programming and reading speed. Further, in the conventional memory device, the floating gate is easily damaged by a large operating voltage. In contrast, since the memory device of the present disclosure has a low operating voltage, it is less likely to damage the components in the device, thereby increasing the endurance of the device.

The features of several embodiments described above enable those skilled in the art to better understand the aspects of the present disclosure. Those skilled in the art will appreciate that the present disclosure may be readily utilized as a basis for designing or modifying other processes and structures to achieve the same objectives and/or achieve the same advantages of the embodiments described herein. It will be appreciated by those skilled in the art that such equivalent structures may be made without departing from the spirit and scope of the present disclosure, and various changes, substitutions and alterations herein may be made without departing from the spirit and scope of the present disclosure.

What is claimed is:

1. A memory cell, comprising:
a thin film transistor layer comprising a channel layer, and a first source/drain structure and a second source/drain structure in contact with opposite sides of the channel layer;
a gate dielectric layer disposed beneath the thin film transistor layer;
a gate conductive layer disposed beneath the gate dielectric layer to control turn-on or turn-off of the channel layer;
a first heater and a second heater respectively disposed over the first source/drain structure and the second source/drain structure;
a phase change layer disposed over the channel layer and in contact with the first heater and the second heater; and
a dielectric layer disposed beneath the phase change layer, wherein the phase change layer is separated from the channel layer by the dielectric layer.

2. The memory cell of claim 1, wherein the phase change layer is disposed over the first heater and the second heater, and bottoms of both ends of the phase change layer are in contact with the first heater and the second heater.

3. The memory cell of claim 2, wherein an upper surface of the first heater, an upper surface of the second heater, and an upper surface of the dielectric layer are coplanar.

4. The memory cell of claim 1, wherein the phase change layer is disposed between the first heater and the second heater, and sidewalls of both ends of the phase change layer are in contact with the first heater and the second heater.

5. The memory cell of claim 4, wherein an upper surface of the first heater, an upper surface of the second heater, and an upper surface of the phase change layer are coplanar.

6. The memory cell of claim 1, further comprising:
a gate metal layer disposed beneath the gate conductive layer.

7. A memory device comprising a plurality of the memory cells of claim 1 connected in series.

8. A method of manufacturing a memory cell, comprising:
providing a precursor structure comprising:
a substrate; and
a gate conductive layer disposed over the substrate;
forming a gate dielectric layer over the gate conductive layer;
forming a thin film transistor layer over the gate dielectric layer, wherein the thin film transistor layer comprises a channel layer, and a first source/drain structure and a second source/drain structure in contact with two sides of the channel layer, wherein the channel layer is completely covered by the gate dielectric layer in a direction perpendicular to a projection;
forming a first heater and a second heater over the first source/drain structure and the second source/drain structure; and
forming a phase change layer in contact with the first heater and the second heater.

9. The method of claim 8, wherein the operation of providing the precursor structure comprises:
forming a dielectric layer over the substrate;
patterning the dielectric layer to form a patterned dielectric layer having an opening; and
forming the gate conductive layer in the opening.

10. The method of claim 8, wherein the operation of forming the thin film transistor layer comprises:
forming an amorphous silicon layer over the gate dielectric layer;
performing an annealing process to crystallize the amorphous silicon layer to form a polysilicon layer or a single-crystal silicon layer; and
performing an implantation process on a portion of the polysilicon layer or the single-crystal silicon layer to form the first source/drain structure and the second source/drain structure, wherein another portion of the polysilicon layer or the single-crystal silicon layer forms the channel layer.

11. The method of claim 8, wherein the operation of forming the first heater and the second heater comprises:
forming a dielectric layer over the thin film transistor layer;
patterning the dielectric layer to form a patterned dielectric layer having a first opening and a second opening, wherein the first opening and the second opening respectively expose the first source/drain structure and the second source/drain structure; and
forming the first heater and the second heater in the first opening and the second opening.

12. The method of claim 11, wherein the operation of forming the phase change layer comprises:
forming a phase change material covering the first heater and the second heater; and
patterning the phase change material to remove a portion of the phase change material to form the phase change layer.

13. The method of claim 8, wherein the operation of forming the first heater and the second heater, and the operation of forming the phase change layer comprise:
forming a dielectric layer over the thin film transistor layer;
forming a phase change material over the dielectric layer;
patterning the dielectric layer and the phase change material to form a patterned dielectric layer and the phase change layer, wherein the patterned dielectric layer and the phase change layer collectively have a first opening and a second opening, and the first opening and the second opening respectively expose the first source/drain structure and the second source/drain structure; and
forming the first heater and the second heater in the first opening and the second opening.

14. The method of claim 13, wherein the operation of forming the first heater and the second heater in the first opening and the second opening comprises:
forming a heater material covering the phase change layer and filling the first opening and the second opening; and
patterning the heater material to form the first heater and the second heater.

15. The method of claim 13, wherein the operation of forming the first heater and the second heater in the first opening and the second opening comprises:
forming a metallic material covering the phase change layer and filling the first opening and the second opening;
performing an annealing process to react a portion of the metallic material in the first opening and the second opening with the first source/drain structure and the second source/drain structure to form the first heater and the second heater; and
removing an unreacted portion of the metallic material.
